(19) United States
(12) Patent Application Publication
(10) Pub. No.: US 2024/0384411 A1
(43) Pub. Date: Nov. 21, 2024

(54) SUBSTRATE PROCESSING APPARATUS WITH AN INJECTOR

(71) Applicant: ASM IP Holding B.V., Almere (NL)

(72) Inventors: Kornelius Haanstra, Nijeveen (NL); Lucian C. Jdira, Nieuw Vennep (NL); Chris G.M. de Ridder, Hoogland (NL); Robin Roelofs, Utrecht (NL); Werner Knaepen, Leuven (BE); Herbert Terhorst, Amersfoort (NL)

(21) Appl. No.: 18/788,528

(22) Filed: Jul. 30, 2024

Related U.S. Application Data
(63) Continuation of application No. 17/530,161, filed on Nov. 18, 2021.
(60) Provisional application No. 63/117,034, filed on Nov. 23, 2020.

(51) Int. Cl. C23C 16/455; C23C 16/458; H01L 21/673; H01L 21/687

(52) U.S. Cl. CPC C23C 16/45544; C23C 16/45553; C23C 16/4583; H01L 21/67303; H01L 21/68764

(57) ABSTRACT

A substrate processing apparatus having a tube, a closed liner lining the interior surface of the tube, a plurality of gas injectors to provide a gas to an inner space of the liner, and, a gas exhaust duct to remove gas from the inner space is disclosed. The liner may have a substantially cylindrical wall delimited by a liner opening at a lower end and being substantially closed for gases above the liner opening. The apparatus may have a boat constructed and arranged moveable into the inner space via the liner opening and provided with a plurality of substrate holders for holding a plurality of substrates over a substrate support length in the inner space. Each of the gas injectors may have a single exit opening at the top and the exit openings of the plurality of injectors are substantially equally divided over the substrate support length.

### CROSS-REFERENCE TO RELATED APPLICATIONS

This application is a continuation of, and claims priority to, U.S. patent application Ser. No. 17/530,161, filed Nov. 18, 2021, and titled SUBSTRATE PROCESSING APPARATUS WITH AN INJECTOR, which claims priority to U.S. Provisional Patent Application Ser. No. 63/117,034, filed Nov. 23, 2020, and titled SUBSTRATE PROCESSING APPARATUS WITH AN INJECTOR, the disclosures of which are hereby incorporated by reference in their entirety.

### FIELD

The present invention relates to substrate processing apparatus comprising:

a tube;

a plurality of gas injectors to provide a gas to an inner space of the apparatus;

a gas exhaust duct to remove gas from the inner space; and,

a boat constructed and arranged moveable into the inner space and provided with a plurality of substrate holders for holding a plurality of substrates over a substrate support length in the inner space.

### BACKGROUND

A substrate processing apparatus such as a vertical processing furnace for processing substrates e.g., semiconductor wafers may include a heater placed around a bell jar-shaped process tube. The upper end of the process tube may be closed, for example by a dome-shaped structure, whereas the lower end surface of the process tube may be open.

Additionally, a liner lining the tube may be provided. Between the liner and the process tube there may be a small circumferential space. The liner may be a closed liner which is closed at its upper end and the lower end may be partially closed by a flange. An inner space bounded by the liner and the flange forms a process chamber in which wafers to be treated may be processed. The flange may be provided with an inlet opening for inserting a wafer boat carrying wafers into the inner space. The wafer boat may be placed on a door that is vertically moveably arranged and that is configured to close off the inlet opening in the flange.

The flange may support a plurality of gas injectors to provide a gas to the inner space. Additionally, a gas exhaust duct may be provided. This gas exhaust may be connected to a vacuum pump for pumping off gas from the inner space. The gas provided by the injectors in the inner space may be a reaction (process) gas for a deposition reaction on the wafers. This reaction gas may also deposit on other surfaces than the wafers, for example it may deposit in and on the injectors within the vertical furnace. Layers created by these deposits may cause clocking and even breakage of the injectors.

### SUMMARY

An improved a substrate processing apparatus comprising:

a tube;

a closed liner configured to line the interior surface of the tube and provided with a liner opening at a lower end and being substantially closed for gases above the liner opening;

a plurality of gas injectors to provide a gas to an inner space of the closed liner;

a gas exhaust duct to remove gas from the inner space; and,

a boat constructed and arranged moveable into the inner space via the liner opening and provided with a plurality of substrate holders for holding a plurality of substrates over a substrate support length in the inner space. The gas injectors may have a single exit opening at the top. The exit openings of the plurality of injectors may be substantially equally divided over the substrate support length.

The various embodiments of the invention may be applied separate from each other or may be combined. Embodiments of the invention will be further elucidated in the detailed description with reference to some examples shown in the figures.

### BRIEF DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 shows a cross-sectional view of a part of a substrate processing apparatus according to an embodiment; and,

FIG. 2 shows schematically a view of a part of a substrate processing apparatus according to a further embodiment.

### DETAILED DESCRIPTION

In this application similar or corresponding features are denoted by similar or corresponding reference signs. The description of the various embodiments is not limited to the examples shown in the figures and the reference number used in the detailed description and the claims are not intended to limit what is described to the examples shown in the figures.

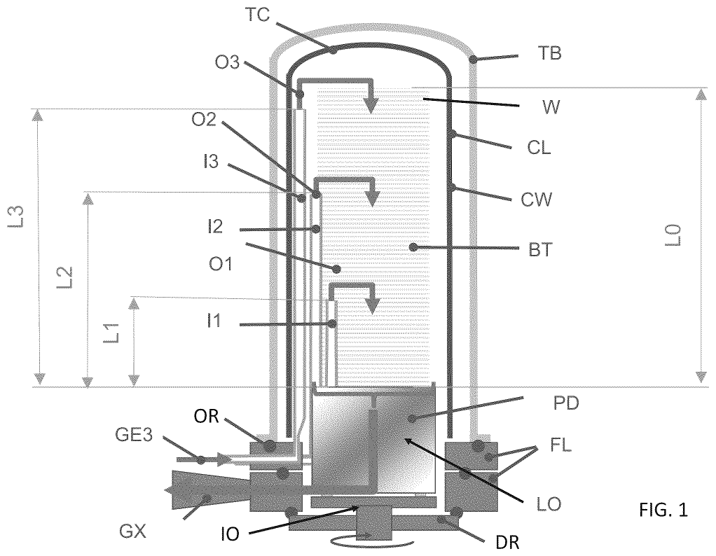

FIG. 1 shows a cross-sectional view of a part of a substrate processing apparatus according to an embodiment. The substrate processing apparatus may comprise:

a tube TB;

a closed liner CL configured to line the interior surface of the tube TB and provided with a liner opening LO at a lower end and being substantially closed for gases above the liner opening;

a boat BT constructed and arranged moveable into the inner space via the liner opening and provided with a plurality of substrate holders for holding a plurality of substrates W over a substrate support length L0 in the inner space;

a plurality of gas injectors I1 to I3 to provide a gas to an inner space of the closed liner CL and,

a gas exhaust GX duct to remove gas from the inner space. The closed liner CL may comprises a substantially cylindrical wall CW delimited by a liner opening LO at a lower end and a top closure at a higher end. The closed liner CL may be substantially closed for gases above the liner opening LO.

The gas injectors I1 to I3 of the plurality of injectors may have a single exit opening O1 to O3 at the top. The gas injectors I1 to I3 of the plurality of injectors may be substantially closed along the length of the injector except for the single exit opening O1 to O3 at the top functioning as a gas exit. The gas injectors I1 to I3 of the plurality of injectors may be provided with a gas entrance of which only the gas entrance GE3 of the injector I3 is depicted. Gas injectors provided with a single exit opening at the top functioning as a gas exit may be stronger then injectors having a plurality of openings along their length functioning a gas exit.

The gas injectors I1 to I3 may have different lengths L1 to L3. The longest injector I3 of the plurality of injectors may extend to close to the top closure TC of the closed liner CL. The longest of the plurality of injectors may extend to within 1 to 20 cm of the top closure TC of the liner CL. Each of the gas injectors I1 to I3 of the plurality of gas injectors may have different lengths so that the single exit opening of each of the injectors exhaust the gas at a different height into the inner space.

The substrate processing apparatus may be provided with a flange FL to support at least the liner CL and being configured to at least partially close off the liner opening LO. The exhaust EX may be provided close to the liner opening LO, for example the exhaust EX may be provided in the flange FL close to the liner opening LO to remove gas from the inner space to create a down flow in the inner space.

The flange FL may comprise an inlet opening IO configured to transfer the boat BT configured to hold a plurality of substrates W over a substrate support length to or from the inner space of the closed liner CL. The openings of a portion of the plurality of injectors I1 to I3 may be substantially equally divided over the substrate support length L0 of the boat BT. The single exit opening of each of the injectors I1, I2, I3 therefore exhaust the gas at a different height into the inner space to the substrates W in the boat BT.

The boat BT may be constructed and arranged to extend in a vertical direction into the reaction chamber and may be provided with a plurality of substrate holders for horizontally holding the plurality of substrates vertically over the substrate support length L0 into the reaction chamber. The apparatus may have N-injectors, for example 2, 3, 4, 5 or 6.

The longest injector L3 of the N-injectors may extend into the reaction chamber along the plurality of substrates W over a distance L3 being equal to 0.6 to 1 time the substrate support length L0. The shortest injector of the N-injectors I1 may extend into the reaction chamber along the plurality of substrates over a distance L1 being equal to 0.1 to 0.4 times the substrate support length L0. The injector 12 which is neither the longest nor the shortest of the N-injectors may extend into the reaction chamber along the plurality of substrates over a distance L2 being equal to 0.3 to 0.7 times the substrate support length L0. The single exit opening of each of the injectors therefore exhaust the gas at a different height into the inner space to the substrates W in the boat BT. The exit openings of the plurality of injectors may therefore be substantially equally divided over the substrate support length L0 which helps in uniformly spreading the process gas over the boat BT. This helps in depositing layers substantially uniformly on the substrates supported over the substrate support length L0 by the boat BT. Small adjustment of the flow of the process gas flowing through the individual injectors may be used to further optimize the uniformity.

For a substrate processing apparatus for processing wafers having a 200 mm diameter a substrate support length H0 may be between 40 and 90 cm, preferably between 50 and 80 cm and most preferably around 60 cm. For a substrate processing apparatus for processing wafers having a 300 mm diameter a substrate support length H0 may be between 60 and 150 cm, preferably between 80 and 130 cm, preferably around 90 or 120 cm.

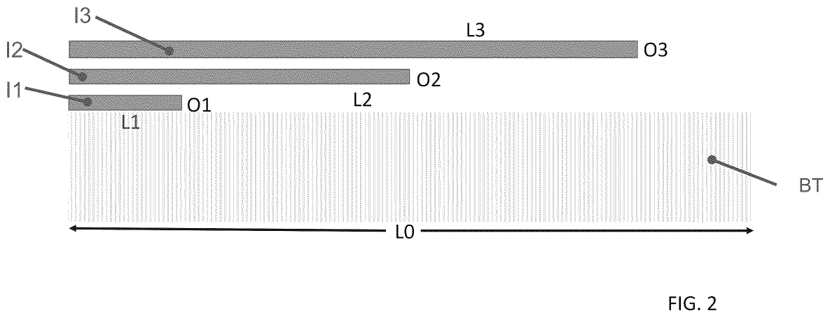

FIG. 2 shows schematically a view of a part of a substrate processing apparatus according to a further embodiment. FIG. 2 shows a relation between the length L1, L2 and L3 of the injectors I1, I2 and I3 and the substrate support length L0 in the boat BT. Each of the gas injectors I1, I2 and I3 has a single exit opening O1, O2 and O3 at the top. The exit openings O1, O2 and O3 of the plurality of N injectors are substantially equally divided over the substrate support length L0. The boat BT may be constructed and arranged to extend in a vertical direction into the inner space of the liner CL. The boat may be provided with a plurality (40 to 180) of substrate holders for horizontally holding the plurality of substrates vertically over the substrate support length L0 in the inner space and the apparatus.

The longest injector of the N-injectors may extend along the plurality of substrates over a distance L3 between (1−1/N) to 1 time the substrate support length L0. In the example of FIG. 2 with n is 3 this would lead to injector I3 having a length L3 between 2/3 and 1 time the L0 substrate support length, preferably around 5/6 the L0 substrate support length.

The shortest injector of the N-injectors may extend along the plurality of substrates over a distance L1 between 0 to 1/N time the substrate support length L0. In the example of FIG. 2 with n is 3 this would lead to injector I1 having a length L1 between 0 and 1/3 time the L0 substrate support length, preferably around 1/6 the L0 substrate support length.

The injector which is neither the longest nor the shortest of the N-injectors may extends along the plurality of substrates over a distance being equal to 1/N to (1−1/N) times the substrate support length L0. In the example of FIG. 2 with n is 3 this would lead to injector I2 having a length L2 between 1/3 and 2/3 time the L0 substrate support length, preferably around 3/6 the L0 substrate support length.

With injector I1 having a length L1 between 0 and 1/3 time the substrate support length L0, the injector I2 having a length L2 between 1/3 and 2/3 time the substrate support length L0 and injector I3 having a length L3 between 2/3 and 1 time the substrate support length L0 it may be assured that the exit openings of the plurality of injectors may be substantially equally divided over the substrate support length L0. The process gas may therefore be substantially uniformly spread over the boat BT. Uniformly spreading the process gas over the boat BT helps depositing uniformly on the substrates supported over the substrate support length L0 by the boat BT. Small adjustment of the flow of the process gas flowing through the individual injectors may be used to further optimize the uniformity.

Returning back to FIG. 1 the substrate processing apparatus may be provided with a vertically movable door DR configured to close off the inlet opening IO in the flange FL. The door DR may be configured to support the boat BT. The horizontal, inner cross-section area of a gas conduction channel inside one the injectors I1 to I3 may be between 100 and 1500 mm².

The horizontal, inner cross-section of a gas conduction channel inside the injector Il to I3 may have a shape with a dimension in a direction tangential to the circumference of the substantially cylindrical liner CL which is larger than a dimension in a radial direction. The substrate processing apparatus may further comprise a vessel for containing silicon precursors and operably connected to the injectors I1 to I3 to provide the silicon precursor as a gas in the inner space. The apparatus may comprise a flow controller to adjust the flow speed of the gas for each of the plurality of gas injectors I1 to I3 to improve the uniformity. For example to give the shorter injectors a higher flow rate then the longer injectors.

The substrate processing apparatus may comprise a heater surrounding the tube TB and configured to heat the interior of the tube. The tube TB may be a low pressure process tube.

The flange FL may be provided to at least partially close the opening of the low tube TB. A vertically movably arranged door DR may be configured to close off a central inlet opening IO in the flange 3 and may be configured to support a wafer boat B that is configured to hold substrates W. The flange 3 may be partially closing an open end of the process tube TB. The door DR may be provided with a pedestal PD. The pedestal PD may be rotated to have the wafer boat BT in the inner space rotating. Under the lowest substrate in the boat BT a flow space may be provided to prevent the flow of reaction gas between the substrates W in the boat BT.

Gas exhaust GX may be constructed and arranged for removing gas from the inner space and may be constructed and arranged below the injectors. By closing the liner CL above the liner opening LO for gases and providing a gas to the inner space with the injector I1 to I3 through the injector opening O1 to O3 at an upper end of the inner space and removing gas from the inner space by the gas exhaust GX at a lower end of the inner space a down flow in the inner space of the closed liner CL may be created. This down flow may transport contamination or reaction by products, particles from the substrate W, the boat B, the liner CL and/or the support flange FL downward to the gas exhaust GX away from the processed substrates W.

The gas exhaust GX for removing gas from the inner space I may be provided below the open end of the closed liner CL. This may be beneficial since a source of contamination of the process chamber may be formed by the contact between the closed liner CL and the flange FL. More specifically the source may exist, at the position where a lower end surface of the closed liner CL at the open end is in contact with the flange FL. During the processing of substrates W, and in particular during unloading of a boat BT after processing, the closed liner CL and the flange FL may be subjected to heat that increases the temperature of both closed liner CL and flange FL. Due to the temperature increase, closed liner CL and flange FL may experience thermal expansion, which causes them to radially expand. As the closed liner CL and the flange FL may have different coefficients of thermal expansion, because for example the closed liner CL may be made from silicon carbide and the flange FL from metal, the closed liner CL and the flange FL may move with respect to each other during expansion. This may cause friction between the lower end surface of the closed liner CL and the upper surface of the flange FL, which may result in contaminants e.g., small particles breaking away from closed liner CL and/or flange FL. The particles may migrate into the process chamber and may contaminate the process chamber and the substrates which are being processed.

By substantially closing the closed liner above the liner opening for gases, providing a process gas to the inner space with the single exit openings of the injectors above the liner opening and removing gas from the inner space by the gas exhaust GX below the liner opening, a down flow in the inner space may be created. This down flow may transport the particles from the liner-flange interface downward to the exhaust away from the processed substrates W.

The tube TB may be made rather thick and of a relatively strong compressive strength material since it may have to compensate for atmospheric pressure with respect to the low pressure on the inside of the tube TB. For example, the low pressure process tube TB can be made of 5 to 8, preferably around 6 mm thick Quartz. Quartz has a very low Coefficient of Thermal Expansion (CTE) of 0.59×10−6 K−1 (see table 1) which makes it more easy to cope with thermal fluctuations in the apparatus. Although the CTE of the deposited materials may be higher (e.g., CTE of Si3N4=3×10−6 K−1, CTE of Si=2.3×10−6 K−1) the differences may be relatively small. When films are deposited onto tube made of quartz, they may adhere even when the tube goes through many large thermal cycles however the risk of contamination may be increasing.

The closed liner CL may circumvent any deposition on the inside of the tube TB and therefore the risk of deposition on the tube TB dropping off may be alleviated. The tube TB may therefore be made from Quartz.

A closed liner CL of silicon carbide (CTE of SiC=4×10−6 K−1) may provide an good match in CTE between deposited film and closed liner, resulting in a greater cumulative thickness before removal of the deposited film from the liner may be required. Mismatches in CTE result in cracking of the deposited film and flaking off, and correspondingly high particle counts, which is undesirable and may be alleviated by using a SIC liner CL. The same mechanism may work for the injectors I1 to I3 which may be may be breaking if too much material with different thermal expansion is deposited in it. It may therefore be advantageously to manufacture the injector I1 to I3 from silicon carbide or silicon. Alternatively the injectors may be made from Quartz.

TABLE 1
Coefficient of Thermal Expansion (CTE) of Materials
in Semiconductor Processing

| Material | Thermal expansion (ppm/K) |
|---|---|
| Quartz | 0.59 |
| Silicon nitride | 3 |
| Silicon | 2.3 |
| Silicon carbide | 4.0 |
| Tungsten | 4.5 |

Whether a material is suitable for the liner CL and/or the injector I1 to I3 may be dependent on the material that is deposited. It is therefore advantageously to be able to use material with substantially the same thermal expansion for the deposited material as for the liner CL and/or the injectors I1 to I3. It may therefore be advantageously to be able to use material with a thermal expansion for the liner CL and/or the injectors I1 to I3 relatively higher than that of quartz. For example Silicon Carbide SiC may be used. The silicon carbide liner may be between 4 to 6,preferably 5 mm thick since it doesn't have to compensate for atmospheric pressure. Pressure compensation may be done with the tube TB.

For systems depositing metal and metal compound materials with a CTE between about 4×10−6 K−1 and 6×10−6 K−1, such as TaN, HfO2 and TaO5, the liner and injector materials preferably may have a CTE between about 4×10−6 K−1 and 9×10−6 K−1, including, e.g., silicon carbide.

For deposition of material with even a higher CTE, the closed liner CL and/or materials for the injectors I1 to I3 may be chosen as for example depicted by table 2.

TABLE 2
Coefficient of Thermal Expansion (CTE) of Ceramic
Construction Materials

| Material | Thermal expansion (ppm/K) |
|---|---|
| Macor | 12.6 |
| Boron Nitride | 11.9 |
| Glass, ordinary | 9 |
| Mullite | 5.4 |

The flange FL may be provided with a groove constructed and arranged for providing a seal such as an O-ring OR therein to provide for a good sealing between the flange FL and the tube TB. This good sealing is necessary because the flange FL, tube TB and the O-ring OR may form part of the pressure barrier between the outside atmospheric pressure and the low pressure inside the tube TB. The O-ring OR may be provided at the interface of the quartz because quartz has relatively low thermal expansion so there is not much movement of the quartz with respect to the O-ring OR which may cause wear of the O-ring OR. Different O-rings may be used between flanges FL and the flange FL and the door DR.

Reducing the pressure with the injector may result in a reduction of the reaction rate within the injector because the reaction rate typically increases with increasing pressure. An additional advantage of a low pressure inside the injector is that gas volume through the injector expands at low pressure and for a constant flow of source gas the residence time of the source gas inside the injector reduces correspondingly. Because of the combination of both, the decomposition of the source gases can be reduced and thereby deposition within the injector may be reduced as well.

Deposition within the injector may cause tensile strength in the injector causing the injector to break when temperature is changing. Less deposition within the injector therefore prolongs the life time of the injector. The injector may be made from a material which has the coefficient of thermal expansion of the material deposited with the process gas. For example, the gas injector may be made from silicon nitride if silicon nitride is deposited or from silicon if silicon is deposited by the process gas. The thermal expansion of the deposited layer within the injector may therefore match the thermal expansion of the injector, decreasing the chance that the gas injector may break during changes of temperature. Silicon carbide may be a suitable material for the injector because it has a thermal expansion which may match many deposited materials

To facilitate the flow of source gas inside the injector, along the length direction of the injector, the injector may be provided with a large inner cross section. In order to be able to accommodate the injector according to the invention inside the reaction space, the tangential size of the injector may be larger than the radial size and the liner delimiting the reaction space may be provided with an outwardly extending bulge to accommodate the injector.

In an embodiment the two source gases, providing the two constituting elements of the binary film, are mixed in the gas supply system prior to entering the injector. This may be the easiest way to ensure a homogeneous composition of the injected gas over the length of the boat BT. However, this is not essential. Alternatively, the two different source gases can be injected via separate injectors and mixed after injection in the reaction space.

The use of a plurality of flow controllers for a plurality of injectors I allows some tuning possibilities of the gas flow. The later may be necessary to fine-tune the uniformity in deposition rate on substrates W over the boat BT. The flow rates may be adjusted to a value between 50 and 1000 sccm.

While specific embodiments have been described above, it will be appreciated that the invention may be practiced otherwise than as described. The descriptions above are intended to be illustrative, not limiting. Thus, it will be apparent to one skilled in the art that modifications may be made to the invention as described in the foregoing without departing from the scope of the claims set out below. Various embodiments may be applied in combination or may be applied independently from one another.

What is claimed is:

1. A method for operating a substrate processing apparatus, the method comprising:
loading a plurality of substrates on a boat into an inner space via a liner opening of the substrate processing apparatus, the boat provided with a plurality of substrate holders that hold the plurality of substrates over a substrate support length in the inner space, the substrate processing apparatus comprising a plurality of gas injectors to provide a gas to the inner space of a closed liner of the substrate processing apparatus, wherein each of the plurality of gas injectors has a single exit opening at a top end of the respective gas injector;
flowing a first gas through a first of the plurality of gas injectors at a first flow rate; and
flowing a second gas through a second of the plurality of gas injectors at a second flow rate, wherein:
the first of the plurality of gas injectors is shorter than the second of the plurality of gas injectors, and
the first flow rate is higher than the second flow rate.

2. The method of claim 1, further comprising flowing a third gas through a third of the plurality of gas injectors at a third flow rate, wherein:
the second of the plurality of gas injectors is shorter than the third of the plurality of gas injectors, and
the second flow rate is higher than the third flow rate.

3. The method of claim 1, wherein the substrate processing apparatus is a vertical processing furnace.

4. The method of claim 1, wherein the single exit openings for each of the plurality of gas injectors are substantially equally divided over the substrate support length.

5. The method of claim 4, wherein the boat is constructed and arranged to extend in a vertical direction into the inner space and provided with the plurality of substrate holders for horizontally holding the plurality of substrates vertically over a substrate support length L0 in the inner space and the substrate processing apparatus has N-injectors.

6. The method of claim 5, wherein a longest injector of the N-injectors extends into the inner space along the plurality of substrates over a distance L3 between (1−1/N) to 1 times the substrate support length L0.

7. The method of claim 5, wherein a shortest injector of the N-injectors extends into the inner space along the plurality of substrates over a distance L1 between 0 to 1/N times the substrate support length L0.

8. The method of claim 1, further comprising:
opening a vertically movable door prior to loading the plurality of substrates; and
closing the vertically movable door after the loading the plurality of substrates on the boat into the inner space, wherein the closing the vertically movable door is configured to close off an inlet opening in a flange of the substrate processing apparatus.

9. The method of claim 1, wherein the first gas and the second gas each comprise a silicon precursor.

10. The method of claim 1, further comprising exhausting the first gas and the second gas via a gas exhaust duct constructed and arrange below the liner opening of the substrate processing apparatus.

11. The method of claim 10, wherein the single exit openings for each of the plurality of gas injectors are disposed above the liner opening.

12. The method of claim 10, wherein the substrate processing apparatus comprises:
a tube including an interior surface; and
the closed liner configured to line the interior surface of the tube, provide the liner opening at a lower end, and be substantially closed for gases above the liner opening.

13. The method of claim 12, wherein the substrate processing apparatus is provided with a flange to support the closed liner, the flange configured to at least partially close off the liner opening.

14. The method of claim 13, wherein the substrate processing apparatus comprises a plurality of flow controllers, each of the plurality of flow controllers corresponding to one of the plurality of gas injectors.

15. The method of claim 14, wherein a flow rate set by each of the plurality of flow controllers is based on a height of each of the plurality of gas injectors.

16. The method of claim 10, wherein responsive to the exhausting the first gas and the second gas, a down flow is generated in the inner space.

17. The method of claim 1, wherein the first flow rate and the second flow rate are each set by a respective flow controller.

18. The method of claim 1, further comprising processing each of the plurality of substrates in response to the flowing the first gas and the flowing the second gas.

19. The method of claim 15, wherein each of the plurality of substrates forms a processed substrate in response to the processing each of the plurality of substrates.

20. The method of claim 18, further comprising unloading the boat after the processing each of the plurality of substrates.
